(19) United States
(12) Patent Application Publication
(10) Pub. No.: US 2025/0228090 A1
(43) Pub. Date: Jul. 10, 2025

(54) DISPLAY APPARATUS

(71) Applicant: Samsung Display Co., LTD., Yongin-si (KR)

(72) Inventor: Jonghyun CHOI, Yongin-si (KR)

(21) Appl. No.: 19/009,768

(22) Filed: Jan. 3, 2025

(30) Foreign Application Priority Data
Jan. 4, 2024 (KR) 10-2024-0001671

(51) Int. Cl. H10K 59/131; H10D 86/40; H10D 86/60

(52) U.S. Cl. CPC H10K 59/131; H10D 86/441; H10D 86/481; H10D 86/60

(57) ABSTRACT

A display apparatus includes: a substrate on which a display element is arranged, a first transistor arranged on the substrate and including a first semiconductor pattern including a silicon semiconductor and a first gate electrode insulated from the first semiconductor pattern and arranged over the first semiconductor pattern, a second transistor arranged on the substrate and including a second semiconductor pattern including an oxide semiconductor and a 2nd-1 gate electrode insulated from the second semiconductor pattern and arranged over the second semiconductor pattern, and a first connection electrode connecting the first semiconductor pattern and the second semiconductor pattern to each other, wherein the first connection electrode is arranged in the same layer in which the 2nd-1 gate electrode is arranged.

This application claims priority to Korean Patent Application No. 10-2024-0001671, filed on Jan. 4, 2024, and all the benefits accruing therefrom under 35 U.S.C. § 119, the content of which in its entirety is herein incorporated by reference.

### BACKGROUND

### 1. Field

One or more embodiments relate to a display apparatus, for example, a display apparatus including an organic light-emitting diode.

### 2. Description of the Related Art

Display apparatuses visually display data. Display apparatuses may provide an image by using light-emitting diodes. The use of display apparatuses has diversified, and various designs for improving the quality of display apparatuses have been attempted.

### SUMMARY

One or more embodiments include a display apparatus that may be driven by using a transistor including a silicon semiconductor and a transistor including an oxide semiconductor to reduce power consumption of the display apparatus and attain high integration. However, such a technical problem is an example, and one or more embodiments are not limited thereto.

Additional aspects will be set forth in part in the description which follows and, in part, will be apparent from the description, or may be learned by practice of the presented embodiments of the disclosure.

According to one or more embodiments, a display apparatus includes: a substrate on which a display element is arranged, a first transistor arranged on the substrate and including a first semiconductor pattern including a silicon semiconductor and a first gate electrode insulated from the first semiconductor pattern and arranged over the first semiconductor pattern, a second transistor arranged on the substrate and including a second semiconductor pattern including an oxide semiconductor and a 2nd-1 gate electrode insulated from the second semiconductor pattern and arranged over the second semiconductor pattern, and a first connection electrode connecting the first semiconductor pattern and the second semiconductor pattern to each other, where the first connection electrode is arranged in the same layer in which the 2nd-1 gate electrode is arranged.

According to one or more embodiments, the display apparatus may further include a second connection electrode connecting the first gate electrode and the second semiconductor pattern to each other.

According to one or more embodiments, the second connection electrode may be arranged in the same layer in which the first connection electrode is arranged.

According to one or more embodiments, the display apparatus may further include a 2nd-2 gate electrode insulated from the second semiconductor pattern and arranged under the second semiconductor pattern.

According to one or more embodiments, the display apparatus may further include a capacitor electrode insulated from the first gate electrode and arranged over the first gate electrode, where the first connection electrode and the capacitor electrode may be arranged in the same layer.

According to one or more embodiments, the first gate electrode and the 2nd-2 gate electrode may be arranged in the same layer.

According to one or more embodiments, the first semiconductor pattern and the second semiconductor pattern may be arranged in the same layer.

According to one or more embodiments, the first connection electrode may be connected to the second semiconductor pattern through a contact hole defined in an insulating layer arranged between the first connection electrode and the second semiconductor pattern, where, in a plan view, the contact hole may include a first region overlapping the first connection electrode and a second region not overlapping the first connection electrode.

According to one or more embodiments, the first connection electrode and a side surface of the insulating layer facing the first region may be in direct contact with each other.

According to one or more embodiments, another insulating layer covering the first connection electrode may be provided in the display apparatus, and the second semiconductor pattern may be in direct contact with the another insulating layer in the second region.

According to one or more embodiments, a display apparatus includes: a substrate; a first transistor arranged on the substrate and including a first semiconductor pattern including a silicon semiconductor and a first gate electrode insulated from the first semiconductor pattern and arranged over the first semiconductor pattern, where the first semiconductor pattern includes a first channel region overlapping the first gate electrode and a first source region and a first drain region, which are disposed on two sides of the first channel region opposite to each other; a second transistor arranged on the substrate, including a second semiconductor pattern including an oxide semiconductor and a 2nd-1 gate electrode insulated from the second semiconductor pattern and arranged over the second semiconductor pattern, and electrically connected to the first transistor, where the second semiconductor pattern includes a second channel region overlapping the 2nd-1 gate electrode and a second source region and a second drain region, which are disposed on two sides of the second channel region opposite to each other; a first connection electrode connected to one of the first source region and the first drain region of the first semiconductor pattern; a second connection electrode connected to one of the second source region and the second drain region of the second semiconductor pattern; and an insulating layer arranged between the first connection electrode and the second connection electrode, where the second connection electrode is arranged under the insulating layer, and the first connection electrode is arranged on the insulating layer.

According to one or more embodiments, a first portion of the second connection electrode may be connected to the one of the second source region and the second drain region of the second semiconductor pattern, and a second portion of the second connection electrode may be connected to the other one of the first source region and the first drain region of the first semiconductor pattern.

According to one or more embodiments, a first portion of the second connection electrode may be connected to the one of the second source region and the second drain region of the second semiconductor pattern, and a second portion of the second connection electrode may be connected to the first gate electrode.

According to one or more embodiments, the second connection electrode and the 2nd-1 gate electrode may be arranged in the same layer.

According to one or more embodiments, the display apparatus may further include a capacitor electrode arranged over the first gate electrode and insulated from the first gate electrode, where the second connection electrode and the capacitor electrode may be arranged in the same layer.

According to one or more embodiments, the display apparatus may further include a capacitor electrode arranged over the first gate electrode and insulated from the first gate electrode, and the second semiconductor pattern and the capacitor electrode may be arranged in a same layer.

According to one or more embodiments, the display apparatus may further include a 2nd-2 gate electrode insulated from the second semiconductor pattern and arranged under the second semiconductor pattern.

According to one or more embodiments, the second connection electrode and the first gate electrode may be arranged in the same layer.

According to one or more embodiments, the first semiconductor pattern and the second semiconductor pattern may be arranged in the same layer.

According to one or more embodiments, the second connection electrode may be connected to the one of the second source region and the second drain region of the second semiconductor pattern through a contact hole defined in another insulating layer arranged between the second connection electrode and the second semiconductor pattern, where, in a plan view, the contact hole may include a first region overlapping the second connection electrode and a second region not overlapping the second connection electrode, and the second semiconductor pattern may include a buffer region overlapping the second region.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of a portion of a display apparatus according to an embodiment;

FIG. 3 is an equivalent circuit diagram showing a sub-pixel circuit configured to drive a sub-pixel and an organic light-emitting diode as a display element connected thereto, according to an embodiment;

FIG. 4 is an equivalent circuit diagram showing a sub-pixel circuit configured to drive a sub-pixel and an organic light-emitting diode as a display element connected thereto, according to another embodiment;

FIG. 5A is an enlarged plan view of a portion of a display apparatus according to an embodiment;

FIG. 5B is a cross-sectional view of the display apparatus of FIG. 5A, taken along line Vb-Vb′ of FIG. 5A;

FIG. 6A is an enlarged plan view of a portion of a display apparatus according to another embodiment;

FIG. 6B is a cross-sectional view of the display apparatus of FIG. 6A, taken along line VIb-VIb′ of FIG. 6A;

FIG. 7A is an enlarged plan view of a portion of a display apparatus according to still another embodiment;

FIG. 7B is a cross-sectional view of the display apparatus of FIG. 7A, taken along line VIIb-VIIb′ of FIG. 7A;

FIG. 8A is an enlarged plan view of a portion of a display apparatus according to yet another embodiment;

FIG. 8B is a cross-sectional view of the display apparatus of FIG. 8A, taken along line VIIIb-VIIIb′ of FIG. 8A;

FIG. 9A is an enlarged plan view of a portion of a display apparatus according to still another embodiment;

FIG. 9B is a cross-sectional view of the display apparatus of FIG. 9A, taken along line IXb-IXb′ of FIG. 9A;

FIG. 10A is an enlarged plan view of a portion of a display apparatus according to yet another embodiment;

FIG. 10B is a cross-sectional view of the display apparatus of FIG. 10A, taken along line Xb-Xb′ of FIG. 10A;

FIG. 11A is an enlarged plan view of a portion of a display apparatus according to still another embodiment;

FIG. 11B is a cross-sectional view of the display apparatus of FIG. 11A, taken along line XIb-XIb′ of FIG. 11A;

FIG. 12A is an enlarged plan view schematically showing a portion of a display apparatus according to an embodiment;

FIG. 12B is a cross-sectional view of the display apparatus of FIG. 12A, taken along line XIIb-XIIb′ of FIG. 12A;

FIG. 12C is a cross-sectional view of the display apparatus of FIG. 12A, taken along line XIIc-XIIc′ of FIG. 12A;

FIG. 13 is an enlarged plan view schematically showing a portion of a display apparatus according to another embodiment; and

FIG. 14 is an enlarged plan view schematically showing a portion of a display apparatus according to still another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof are omitted.

While such terms as “first” and “second” may be used to describe various elements, such elements must not be limited to the above terms. The above terms are used only to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being “on” another layer, region, or element, it may be directly or indirectly on the other layer, region, or element. That is, for example, intervening layers, regions, or elements may be present. In contrast, when an element is referred to as being “directly on” another element, there are no intervening elements present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

When an embodiment may be implemented differently, a certain process order may be performed differently from the described order. For example, two consecutively described processes may be performed substantially at the same time or performed in an order opposite to the described order.

As used herein, the expression “A and/or B” refers to A, B, or A and B. In addition, the expression “at least one of A or B” refers to A, B, or A and B.

It will be further understood that, when layers, regions, or elements are referred to as being “connected to” each other, they may be directly connected to each other and/or may be indirectly connected to each other with intervening layers, regions, or elements therebetween. For example, when layers, regions, or elements are referred to as being electrically connected to each other, they may be directly electrically connected to each other and/or may be indirectly electrically connected to each other with intervening layers, regions, or elements therebetween.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

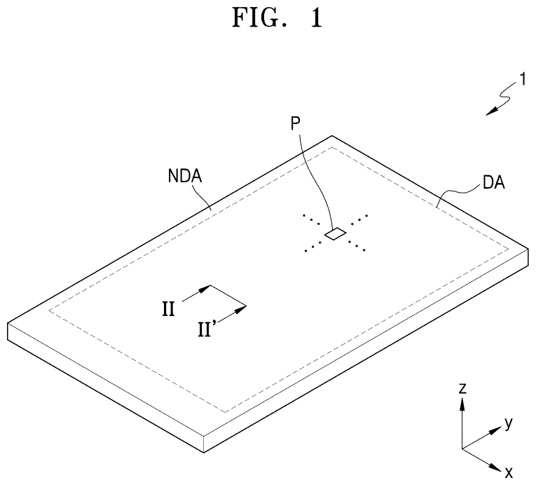

FIG. 1 is a schematic perspective view of a display apparatus 1 according to an embodiment.

Referring to FIG. 1, the display apparatus 1 may include a display area DA and a non-display area NDA outside the display area DA. The display area DA may display an image through a sub-pixel P arranged in the display area DA. The non-display area NDA is arranged outside the display area DA, is an area that does not display an image, and may surround the entirety of the display area DA. A driver for supplying an electrical signal or power to the display area DA may be arranged in the non-display area NDA. A pad, which is an area to which an electronic element or a printed circuit board may be electrically connected, may be arranged in the non-display area NDA.

In an embodiment, FIG. 1 shows the display area DA having a polygonal shape (e.g., a quadrangular shape) in which a length of the display area DA in a direction x is less than a length thereof in a direction y. However, in another embodiment, the display area DA may have a polygonal shape (e.g., a quadrangular shape) in which a length of the display area DA in the direction y is less than a length thereof in the direction x. Although FIG. 1 shows the display area DA having an approximately quadrangular shape, one or more embodiments are not limited thereto. In another embodiment, the display area DA may have various shapes such as an N-gonal shape (where N is a natural number equal to or greater than 3), a circular shape, or an oval shape. FIG. 1 shows a corner portion of the display area DA including a vertex where a straight line and another straight line meet. However, in another embodiment, the display area DA may have a polygonal shape in which a corner portion is curved.

Although a case where the display apparatus 1 is an electronic device such as a smartphone is described below for convenience, the display apparatus 1 described herein is not limited thereto. The display apparatus 1 may be applied to not only portable electronic devices, such as a mobile phone, a smartphone, a tablet personal computer (“PC”), a mobile communication terminal, an electronic notebook, an e-book, a portable multimedia player (“PMP”), a navigation system, and an ultra-mobile PC (“UMPC”), but also various products, such as a television, a notebook computer, a monitor, a billboard, and the Internet of things (“IoT”). In addition, the display apparatus 1 according to an embodiment may be applied to wearable devices, such as a smartwatch, a watch phone, a glasses-type display, and a head-mounted display (“HMD”). In addition, the display apparatus 1 according to an embodiment may be applied to a car's instrument panel, a center information display (“CID”) placed on a car's center fascia or dashboard, a room mirror display replacing a car's side mirror, or a display screen placed on the back of a front seat as entertainment for a car's rear seat.

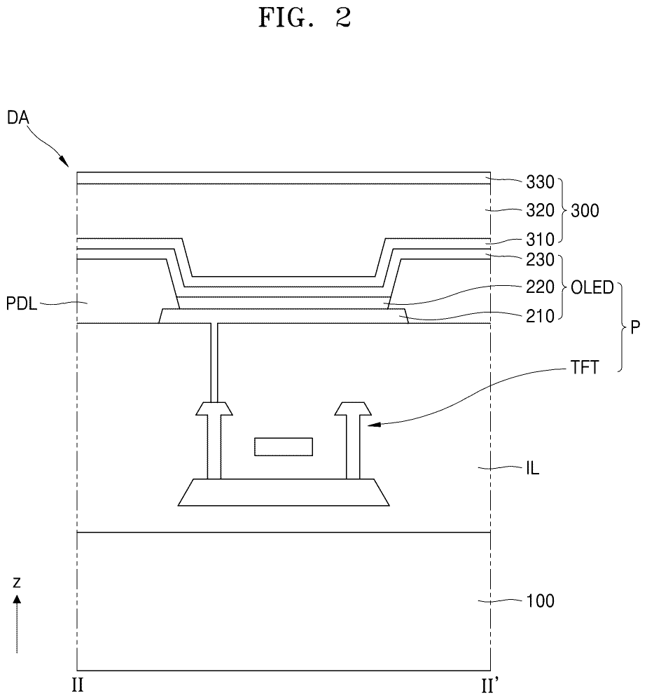

FIG. 2 is a schematic cross-sectional view of a portion of the display apparatus 1 according to an embodiment.

Referring to FIG. 2, the sub-pixel P including an organic light-emitting diode OLED and a thin-film transistor TFT may be disposed over a substrate 100 in the display area DA.

The substrate 100 may include glass or polymer resin. The substrate 100 including polymer resin may be flexible, rollable, or bendable. The substrate 100 may have a multi-layer structure including a layer and an inorganic layer, the layer including polymer resin.

The thin-film transistor TFT, the organic light-emitting diode OLED electrically connected to the thin-film transistor TFT, and an insulating layer IL disposed therebetween may be disposed on the substrate 100. The thin-film transistor TFT may be configured to provide a voltage to drive the organic light-emitting diode OLED. The insulating layer IL may include a plurality of layers.

The organic light-emitting diode OLED may include a sub-pixel electrode 210, an intermediate layer 220, and an opposite electrode 230.

The sub-pixel electrode 210 may be disposed on the insulating layer IL. The sub-pixel electrode 210 may be a transparent or semitransparent electrode or may be a reflection electrode. When the sub-pixel electrode 210 is a transparent or semitransparent electrode, the sub-pixel electrode 210 may include, for example, indium tin oxide (“ITO”), indium zinc oxide (“IZO”), zinc oxide (ZnO), indium oxide (In₂O₃), indium gallium oxide (“IGO”), or aluminum zinc oxide (“AlZO”). When the sub-pixel electrode 210 is a reflection electrode, the sub-pixel electrode 210 may include a reflection layer including silver (Ag), magnesium (Mg), aluminum (AI), platinum (Pt), palladium (Pd), gold (Au), nickel (Ni), neodymium (Nd), iridium (Ir), chromium (Cr), or a compound thereof, and a layer including ITO, IZO, ZnO, or In₂O₃ on the reflection layer. In an embodiment, the sub-pixel electrode 210 may have a structure in which an ITO layer, an Ag layer, and an ITO layer are sequentially stacked on one another. However, one or more embodiments are not limited thereto, and the sub-pixel electrode 210 may include various materials, and a structure of the sub-pixel electrode 210 may also have various modifications such as a single-layer or multi-layer structure.

A sub-pixel-defining layer PDL may cover an edge area (or the edge) of the sub-pixel electrode 210. The sub-pixel-defining layer PDL may define an opening therein exposing a portion of the sub-pixel electrode 210. The opening in the sub-pixel-defining layer PDL may correspond to an area where light of the organic light-emitting diode OLED is emitted, and may define the sub-pixel P or an emission area of the organic light-emitting diode OLED.

The intermediate layer 220 may be disposed on the sub-pixel electrode 210. The intermediate layer 220 may include an organic emission layer including a low-molecular weight material or a polymer material. The intermediate layer 220 may have a structure in which a hole injection layer, a hole transport layer, an organic emission layer, an electron transport layer and/or an electron injection layer are stacked in a single or complex structure.

The opposite electrode 230 may be disposed on the intermediate layer 220. The opposite electrode 230 may be a transparent or semitransparent electrode. When the opposite electrode 230 is a transparent or semitransparent electrode, the opposite electrode 230 may include one or more materials selected from Ag, Al, Mg, Li, Ca, Cu, LiF/Ca, LiF/Al, MgAg, and CaAg, and may be in the form of a thin film having a thickness of several to tens of nm. A structure and material of the opposite electrode 230 is not limited thereto and may have various modifications.

An encapsulation layer 300 may be disposed on the opposite electrode 230. The encapsulation layer 300 may include at least one inorganic encapsulation layer and at least one organic encapsulation layer. For example, the encapsulation layer 300 may include a first inorganic encapsulation layer 310, a second inorganic encapsulation layer 330, and an organic encapsulation layer 320 therebetween. The first and second inorganic encapsulation layers 310 and 330 may include an inorganic insulating material such as silicon oxide (SiOₓ), silicon nitride (SiNₓ) and/or silicon oxynitride (SiON), and the organic encapsulation layer 320 may include at least one organic insulating material selected from polyethylene terephthalate, polyethylene naphthalate, polycarbonate, polyimide, polyethylene sulfonate, polyoxymethylene, polyarylate, and hexamethyldisiloxane.

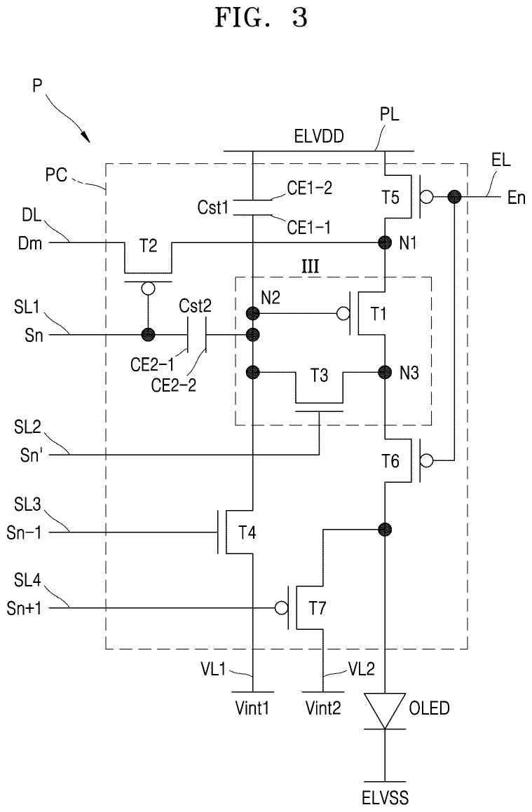

FIG. 3 is an equivalent circuit diagram showing a sub-pixel circuit PC configured to drive the sub-pixel P and the organic light-emitting diode OLED as a display element connected thereto, according to an embodiment.

Referring to FIG. 3, the sub-pixel circuit PC includes a plurality of first to seventh transistors T1, T2, T3, T4, T5, T6, and T7, a first capacitor Cst1, and a second capacitor Cst2. In addition, the sub-pixel circuit PC is connected to a plurality of signal lines, first and second initialization voltage lines VL1 and VL2, and a power voltage line PL. The signal lines may include a data line DL, a first scan line SL1, a second scan line SL2, a third scan line SL3, a fourth scan line SL4, and an emission control line EL. In another embodiment, at least one of the signal lines, the first and second initialization voltage lines VL1 and VL2 and/or the power voltage line PL may be shared by neighboring sub-pixel circuits.

The power voltage line PL may be configured to transfer a first power voltage ELVDD to the first transistor T1. The first initialization voltage line VL1 may be configured to transfer a first initialization voltage Vint1 for initializing the first transistor T1 to the sub-pixel circuit PC. The second initialization voltage line VL2 may be configured to transfer a second initialization voltage Vint2 for initializing the organic light-emitting diode OLED to the sub-pixel circuit PC.

In FIG. 3, the third transistor T3 and the fourth transistor T4 among the first to seventh transistors T1 to T7 are shown as being implemented as n-channel MOSFETs (“NMOS”), and the others are shown as being implemented as p-channel MOSFETs (“PMOS”).

The first transistor T1 is connected to the power voltage line PL via the fifth transistor T5 and is electrically connected to the organic light-emitting diode OLED via the sixth transistor T6. The first transistor T1 serves as a driving transistor and is configured to receive a data signal Dm according to a switching operation of the second transistor T2 and supply a driving current to the organic light-emitting diode OLED.

The second transistor T2 is a switching transistor, is connected to the first scan line SL1 and the data line DL, and is connected to the power voltage line PL via the fifth transistor T5. The second transistor T2 is turned on according to a first scan signal Sn received through the first scan line SL1 to perform a switching operation for transmitting the data signal Dm transmitted through the data line DL to a first node N1.

The third transistor T3 is a compensation transistor, is connected to the second scan line SL2, and is connected to the organic light-emitting diode OLED via the sixth transistor T6. The third transistor T3 is turned on according to a second scan signal Sn′ received through the second scan line SL2 to diode-connect the first transistor T1.

The fourth transistor T4 is a first initialization transistor, is connected to the third scan line SL3, which is a previous scan line, and the first initialization voltage line VL1, and is turned on according to a third scan signal Sn−1, which is a previous scan signal received through the third scan line SL3, to transfer the first initialization voltage Vint1 from the first initialization voltage line VL1 to a gate electrode of the first transistor T1 and initialize a voltage of the gate electrode of the first transistor T1.

The fifth transistor T5 may be an operation control transistor, and the sixth transistor T6 may be an emission control transistor. The fifth transistor T5 and the sixth transistor T6 are connected to the emission control line EL, and are simultaneously turned on according to an emission control signal En received through the emission control line EL to form a current path that allows a driving current to flow in a direction from the power voltage line PL to the organic light-emitting diode OLED.

The seventh transistor T7 is a second initialization transistor, is connected to the fourth scan line SL4, which is a next scan line, and the second initialization voltage line VL2, and may be turned on according to a fourth scan signal Sn+1, which is a next scan signal received through the fourth scan line SL4, to transfer the second initialization voltage Vint2 from the second initialization voltage line VL2 to the organic light-emitting diode OLED and initialize the organic light-emitting diode OLED. In another embodiment, the seventh transistor T7 may be omitted.

The first capacitor Cst1 may include a 1st-1 capacitor electrode CE1-1 and a 1st-2 capacitor electrode CE1-2. The 1st-1 capacitor electrode CE1-1 is connected to the gate electrode of the first transistor T1, and the 1st-2 capacitor electrode CE1-2 is connected to the power voltage line PL. The first capacitor Cst1 may maintain a voltage applied to the gate electrode of the first transistor T1 by storing and maintaining a voltage corresponding to a voltage difference between two ends of the power voltage line PL and the gate electrode of the first transistor T1.

The second capacitor Cst2 may include a 2nd-1 capacitor electrode CE2-1 and a 2nd-2 capacitor electrode CE2-2. The 2nd-1 capacitor electrode CE2-1 is connected to the first scan line SL1 and a gate electrode of the second transistor T2. The 2nd-2 capacitor electrode CE2-2 is connected to the gate electrode of the first transistor T1 and the 1st-1 capacitor electrode CE1-1 of the first capacitor Cst1. The second capacitor Cst2 is a boosting capacitor, and when the first scan signal Sn of the first scan line SL1 is a voltage for turning off the second transistor T2, a voltage of a node may be boosted to decrease a voltage for displaying black. In another embodiment, the second capacitor Cst2 may be omitted.

The organic light-emitting diode OLED may include the sub-pixel electrode 210 (refer to FIG. 2) and the opposite electrode 230 (refer to FIG. 2). The sub-pixel electrode 210 (of FIG. 2) may receive the first power voltage ELVDD via the fifth transistor T5, the first transistor T1, and the sixth transistor T6. The opposite electrode 230 (of FIG. 2) may receive a second power voltage ELVSS. The organic light-emitting diode OLED receives a current caused by a potential difference between the first power voltage ELVDD and the second power voltage ELVSS, that is, a driving current, and thus emits light, thereby displaying an image.

In the present embodiment, at least one of the plurality of transistors T1 to T7 includes a semiconductor layer including oxide, and the others include a semiconductor layer including silicon. For example, the first transistor T1, which directly affects the brightness of a display apparatus, may be configured to include a semiconductor layer composed of polycrystalline silicon with high reliability, for example, low-temperature polycrystalline silicon (“LTPS”), and thus, a high-resolution display apparatus may be implemented.

Meanwhile, an oxide semiconductor has high carrier mobility and low leakage current, and accordingly, a voltage drop is not significant even when a driving time is long. That is, a change in a color of an image due to a voltage drop is not significant even during low-frequency driving, which makes low-frequency driving possible. As described above, because an oxide semiconductor has low leakage current, at least one of the third transistor T3 and the fourth transistor T4 connected to the gate electrode of the first transistor T1 may include an oxide semiconductor, and thus, a leakage current that may flow to the gate electrode of the first transistor T1 may be prevented and power consumption may also be reduced.

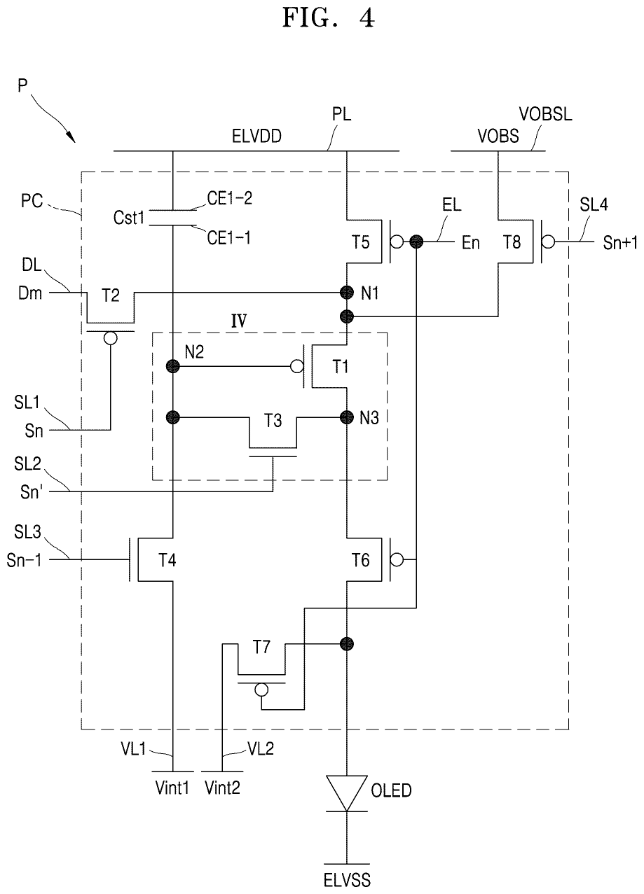

FIG. 4 is an equivalent circuit diagram showing the sub-pixel circuit PC configured to drive the sub-pixel P and the organic light-emitting diode OLED as a display element connected thereto, according to another embodiment. Features overlapping with those of the embodiment shown in FIG. 3 are omitted below, and differences are mainly described.

Referring to FIG. 4, the sub-pixel circuit PC includes a plurality of first to eighth transistors T1, T2, T3, T4, T5, T6, T7, and T8, and the first capacitor Cst1.

In FIG. 4, the third transistor T3 and the fourth transistor T4 among the first to eighth transistors T1 to T8 are shown as being implemented as n-channel MOSFETs (NMOS), and the others are shown as being implemented as p-channel MOSFETs (PMOS).

The seventh transistor T7 is a second initialization transistor, is connected to the emission control line EL and the second initialization voltage line VL2, and may be turned on according to the emission control signal En received through the emission control line EL to transfer the second initialization voltage Vint2 from the second initialization voltage line VL2 to the organic light-emitting diode OLED and initialize the organic light-emitting diode OLED.

The eighth transistor T8 is a stress transistor, is connected to the fourth scan line SL4, which is a next scan line, and a stress voltage line VOBSL, and may be turned on according to the fourth scan signal Sn+1, which is a next scan signal received through the fourth scan line SL4, to provide a stress voltage VOBS from the stress voltage line VOBSL to the first transistor T1. The stress voltage VOBS may be equal to or less than the first power voltage ELVDD. The stress voltage VOBS may be provided to the first transistor T1 through the eighth transistor T8, and thus, hysteresis, for example, a stress bias effect, that may occur in the first transistor T1, may be reduced.

Unlike that shown in FIG. 3, the second capacitor Cst2 (of FIG. 3) may be omitted in the embodiment shown in FIG. 4.

In the present embodiment, at least one of the plurality of transistors T1 to T8 includes a semiconductor layer including oxide, and the others include a semiconductor layer including silicon. For example, the first transistor T1 may be configured to include a semiconductor layer composed of polycrystalline silicon, for example, low-temperature polycrystalline silicon (LTPS). At least one of the third transistor T3 and the fourth transistor T4 may include a semiconductor layer composed of an oxide semiconductor.

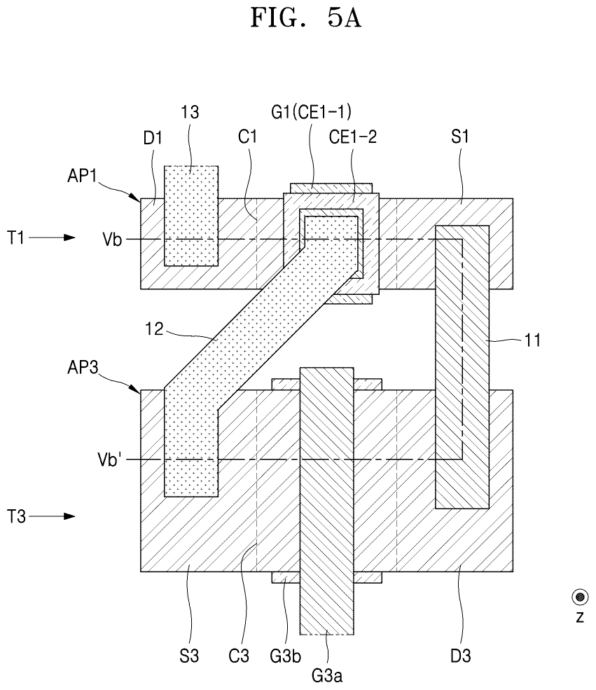

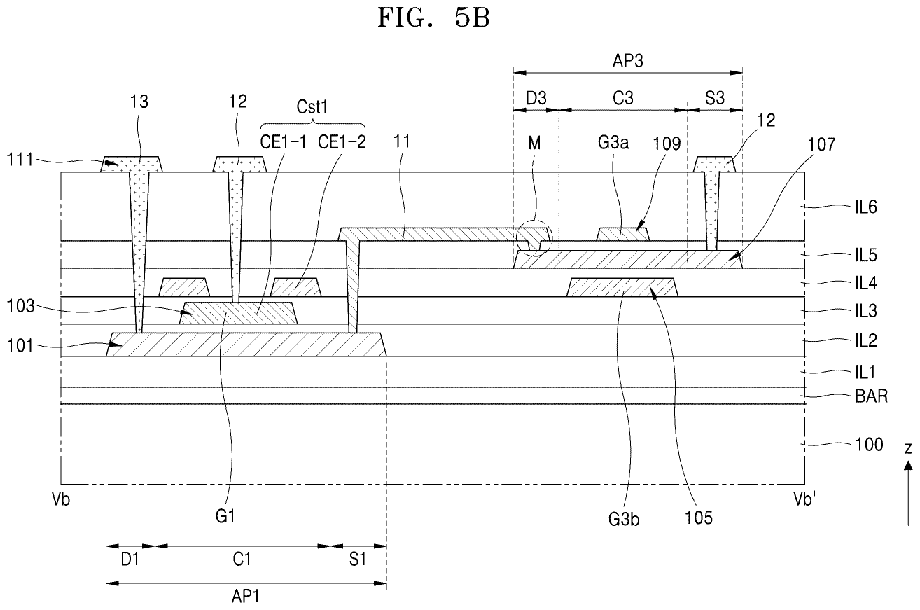

FIGS. 5A, 6A, 7A, 8A, 9A, 10A, and 11A, which will be referred to below, are a variety of examples of a plan view showing a region III of FIG. 3 or a region IV of FIG. 4. Accordingly, it will be understood that the structure shown in each of FIGS. 5A, 6A, 7A, 8A, 9A, 10A, or 11A is a structure that may be applied to not only the embodiment shown in FIG. 3 but also the embodiment shown in FIG. 4.

FIG. 5A is an enlarged plan view of a portion of a display apparatus according to an embodiment. FIG. 5B is a cross-sectional view of the display apparatus of FIG. 5A, taken along line Vb-Vb′ of FIG. 5A. As used herein, the “plan view” means a view in a thickness direction (z-axis) of the substrate 100.

Referring to FIGS. 5A and 5B together, the first transistor T1 may include a first semiconductor pattern AP1 and a first gate electrode G1, and the third transistor T3 may include a third semiconductor pattern AP3, a 3rd-1 gate electrode G3a, and a 3rd-2 gate electrode G3b.

The first semiconductor pattern AP1 may include a first channel region C1 overlapping the first gate electrode G1 in a plan view, and a first drain region D1 and a first source region S1, which are disposed on two sides of the first channel region C1 opposite to each other. The first drain region D1 and the first source region S1 may be regions doped with impurities. In some embodiments, positions of the first drain region D1 and the first source region S1 may be reversed in a different way from those shown in FIG. 5A. That is, the first drain region D1 and the first source region S1 are interchangeable. In some embodiments, the first semiconductor pattern AP1 may include a low-temperature polycrystalline silicon semiconductor and may be implemented as PMOS.

The first gate electrode G1 may be disposed over the first semiconductor pattern AP1 to overlap the first channel region C1 in a plan view. The first gate electrode G1 may be formed simultaneously with the 1st-1 capacitor electrode CE1-1 of the first capacitor Cst1 to serve as both the first gate electrode G1 and the 1st-1 capacitor electrode CE1-1. The 1st-2 capacitor electrode CE1-2 of the first capacitor Cst1 may be disposed over the first gate electrode G1 to overlap the first channel region C1 and the first gate electrode G1 in a plan view. In another embodiment, the first gate electrode G1 and the 1st-1 capacitor electrode CE1-1 may be formed separately.

The third semiconductor pattern AP3 may include a third channel region C3 overlapping the 3rd-1 and 3rd-2 gate electrodes G3a and G3b in a plan view, and a third drain region D3 and a third source region S3, which are disposed on two sides of the third channel region C3 opposite to each other. The third drain region D3 and the third source region S3 may be regions doped with impurities. In some embodiments, positions of the third drain region D3 and the third source region S3 may be reversed in a different way from those shown in FIG. 5A. That is, the third drain region D3 and the third source region S3 are interchangeable. In some embodiments, the third semiconductor pattern AP3 may include an oxide semiconductor and may be implemented as NMOS.

The 3rd-1 gate electrode G3a may be disposed over the third semiconductor pattern AP3 to overlap the third channel region C3 in a plan view. The 3rd-2 gate electrode G3b may be disposed under the third semiconductor pattern AP3 to overlap the third channel region C3.

A first connection electrode 11 may overlap and be connected to the first source region S1 and the third drain region D3 in a plan view to connect the first source region S1 and the third drain region D3 to each other, thereby connecting the first semiconductor pattern AP1 and the third semiconductor pattern AP3 to each other. A second connection electrode 12 may overlap and be connected to the first gate electrode G1 and the third source region S3 in a plan view to connect the first gate electrode G1 and the third source region S3 to each other, thereby connecting the first gate electrode G1 and the third semiconductor pattern AP3 to each other. In some embodiments, the second connection electrode 12 may be connected to the first gate electrode G1 through an opening defined in the 1st-2 capacitor electrode CE1-2. A third connection electrode 13 may be connected to the first drain region D1. Referring to FIGS. 3 and 4 together, a third node N3 may be positioned on the first connection electrode 11, a second node N2 may be positioned on the second connection electrode 12, and the third connection electrode 13 may extend toward the first node N1.

A barrier layer BAR and first to sixth insulating layers IL1, IL2, IL3, IL4, IL5, and IL6 may be sequentially disposed on the substrate 100. The barrier layer BAR and the first to sixth insulating layers IL1, IL2, IL3, IL4, IL5, and IL6 may each include an inorganic insulating material such as silicon oxide (SiOₓ), silicon nitride (SiNₓ) and/or silicon oxynitride (SiON).

The first semiconductor pattern AP1 may be disposed on the first insulating layer IL1. A layer where the first semiconductor pattern AP1 is positioned may be defined as a first semiconductor layer 101.

The second insulating layer IL2 may be disposed over the first semiconductor layer 101. The first gate electrode G1 may be disposed on the second insulating layer IL2 to overlap the first channel region C1 of the first semiconductor pattern AP1 in a plan view. The first semiconductor pattern AP1 and the first gate electrode G1 may be insulated from each other by the second insulating layer IL2. A layer where the first gate electrode G1 is positioned may be defined as a first electrode layer 103.

The third insulating layer IL3 may be disposed over the first electrode layer 103. The 1st-2 capacitor electrode CE1-2 may be disposed on the third insulating layer IL3. As described above, in some embodiments, the first gate electrode G1 may also serve as the 1st-1 capacitor electrode CE1-1. The 1st-1 capacitor electrode CE1-1 and the 1st-2 capacitor electrode CE1-2 may be included in the first capacitor Cst1. The 1st-2 capacitor electrode CE1-2 may define an opening therein overlapping the first gate electrode G1 in a plan view.

The 3rd-2 gate electrode G3b may be disposed on the third insulating layer IL3 to overlap the third channel region C3 of the third semiconductor pattern AP3 in a plan view. The third semiconductor pattern AP3 and the 3rd-2 gate electrode G3b may be insulated from each other by the fourth insulating layer IL4 disposed therebetween. A layer where the 1st-2 capacitor electrode CE1-2 and the 3rd-2 gate electrode G3b are positioned may be defined as a second electrode layer 105. In some embodiments, the 1st-2 capacitor electrode CE1-2 and the 3rd-2 gate electrode G3b may be formed during the same process.

The fourth insulating layer IL4 may be disposed over the second electrode layer 105. The third semiconductor pattern AP3 may be apart from the first semiconductor pattern AP1 and disposed on the fourth insulating layer IL4. A layer where the third semiconductor pattern AP3 is positioned may be defined as a second semiconductor layer 107.

The fifth insulating layer IL5 may be disposed over the second semiconductor layer 107. The 3rd-1 gate electrode G3a may be disposed on the fifth insulating layer IL5 to overlap the third channel region C3 of the third semiconductor pattern AP3 in a plan view. The third semiconductor pattern AP3 and the 3rd-1 gate electrode G3a may be insulated from each other by the fifth insulating layer IL5. A layer where the 3rd-1 gate electrode G3a is positioned may be defined as a third electrode layer 109.

The first connection electrode 11 may be disposed on the fifth insulating layer IL5 and may be connected to the first source region S1 of the first semiconductor pattern AP1 and the third drain region D3 of the third semiconductor pattern AP3. The first connection electrode 11 may overlap the first source region S1 in a plan view and be connected to the first source region S1 through a first opening defined in the second to fifth insulating layers IL2, IL3, IL4, and IL5. The first connection electrode 11 may overlap the third drain region D3 in a plan view and be connected to the third drain region D3 through a second opening defined in the fifth insulating layer IL5. The first opening and the second opening may be formed during the same process or may be formed during different processes. In some embodiments, when the first opening and the second opening are formed during the same process, after the first and second openings are formed through an etching process, a buffered oxide etch (“BOE”) process may be used to remove an inorganic material remaining in the first opening. In this regard, the second opening may be covered by a photoresist to protect an upper surface of the third semiconductor pattern AP3 (e.g., an upper surface of the third drain region D3) exposed by the second opening. After the BOE process is performed, the second opening may be opened again by removing the photoresist. In some embodiments, the first connection electrode 11 may be arranged in the same layer as the 3rd-1 gate electrode G3a. That is, the first connection electrode 11 may be positioned in the third electrode layer 109. In some embodiments, the first connection electrode 11 and the 3rd-1 gate electrode G3a may be formed during the same process.

The sixth insulating layer IL6 may be disposed over the third electrode layer 109. The second connection electrode 12 and the third connection electrode 13 may be disposed on the sixth insulating layer IL6. The second connection electrode 12 may be connected to the first gate electrode G1 and the third source region S3. The second connection electrode 12 may overlap the first gate electrode G1 in a plan view and be connected to the first gate electrode G1 through an opening defined in the third to sixth insulating layers IL3, IL4, IL5, and IL6. The second connection electrode 12 may overlap the third source region S3 in a plan view and be connected to the third source region S3 through an opening defined in the fifth and sixth insulating layers IL5 and IL6. The third connection electrode 13 may overlap the first drain region D1 in a plan view and be connected to the first drain region D1 through an opening defined in the second to sixth insulating layers IL2, IL3, IL4, IL5, and IL6. A layer where the second connection electrode 12 and the third connection electrode 13 are positioned may be defined as a fourth electrode layer 111. In some embodiments, the second connection electrode 12 and the third connection electrode 13 may be formed during the same process. As used herein, when describing a location of the first, second or third connection electrode 11, 12 or 13 in a multiple layer structure, it is considered that a location of a “major plate portion” of the connection electrode is described. For example, while the first connection electrode 11 includes the major plate portion parallel to a plane defined by the x-axis and y-axis, a first vertical portion extending from the major plate portion to the first semiconductor pattern AP1 in the z-axis direction, and a second vertical portion extending from the major plate portion to the third semiconductor pattern AP3 in the z-axis, when saying that the first connection electrode 11 is arranged in the third electrode layer 109, it means that the major plate portion of the first connection electrode 11 is arranged in the third electrode layer 109.

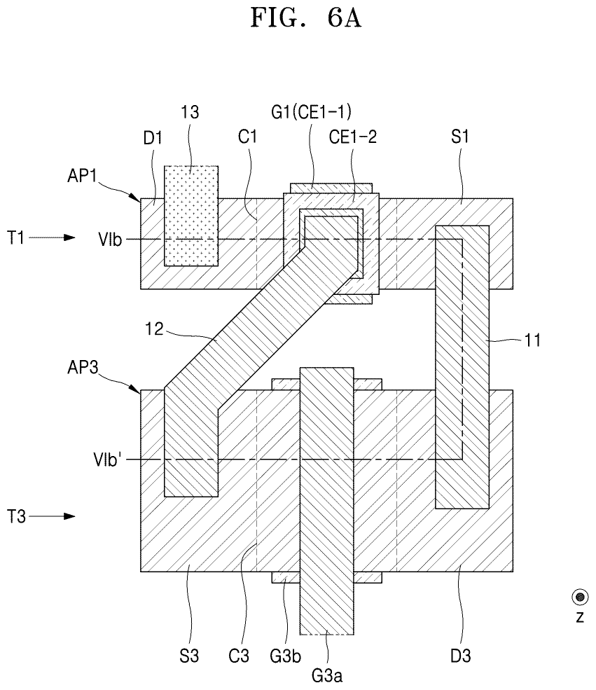

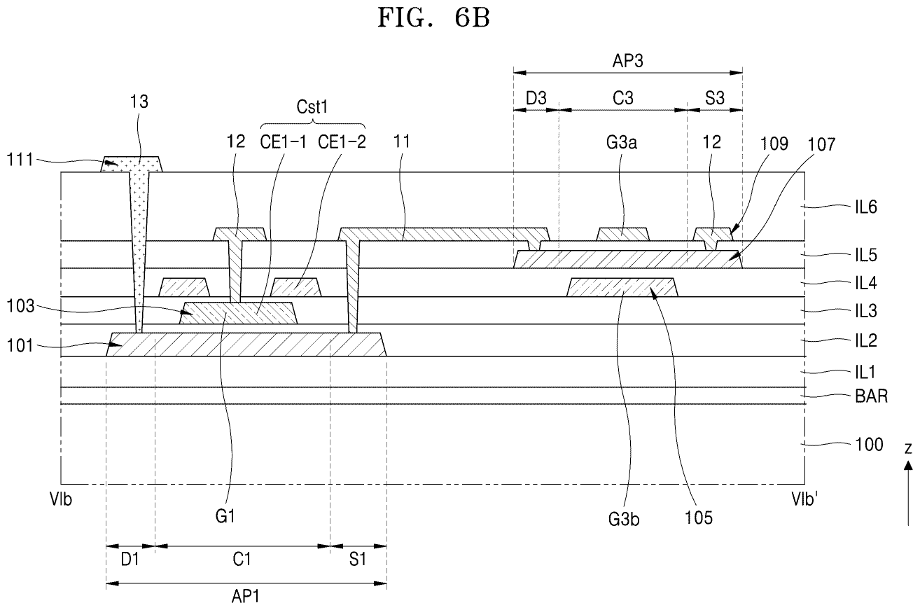

FIG. 6A is an enlarged plan view of a portion of a display apparatus according to another embodiment. FIG. 6B is a cross-sectional view of the display apparatus of FIG. 6A, taken along line VIb-VIb′ of FIG. 6A.

Referring to FIGS. 6A and 6B together, the second connection electrode 12 may be disposed on a layer different from the layer in the embodiment shown in FIGS. 5A and 5B.

The second connection electrode 12 may be disposed on the fifth insulating layer IL5. For example, the second connection electrode 12 may be disposed between the fifth insulating layer IL5 and the sixth insulating layer IL6. The second connection electrode 12 may be arranged in the same layer as the first connection electrode 11 and the 3rd-1 gate electrode G3a. In other words, the first connection electrode 11, the second connection electrode 12, and the 3rd-1 gate electrode G3a may be positioned in the third electrode layer 109. In some embodiments, the first connection electrode 11, the second connection electrode 12, and the 3rd-1 gate electrode G3a may be formed during the same process.

The second connection electrode 12 may overlap the first gate electrode G1 in a plan view and be connected to the first gate electrode G1 through an opening defined in the third to fifth insulating layers IL3, IL4, and IL5. The second connection electrode 12 may overlap the third source region S3 in a plan view and be connected to the third source region S3 through an opening defined in the fifth insulating layer IL5.

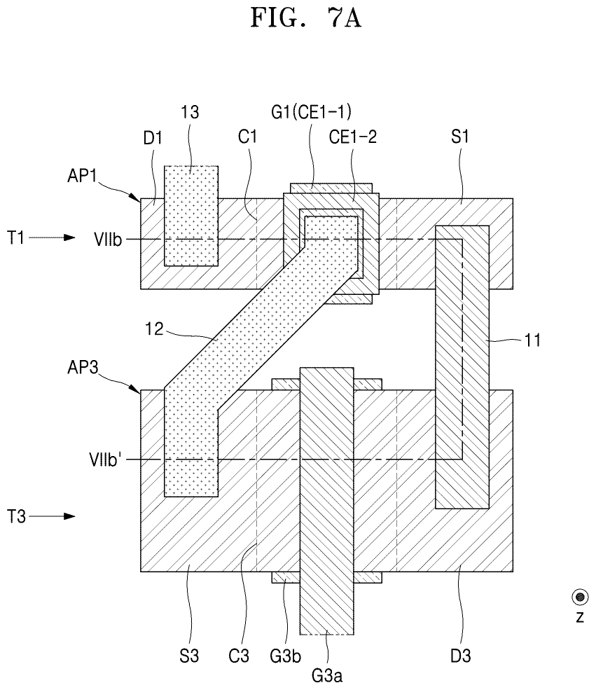

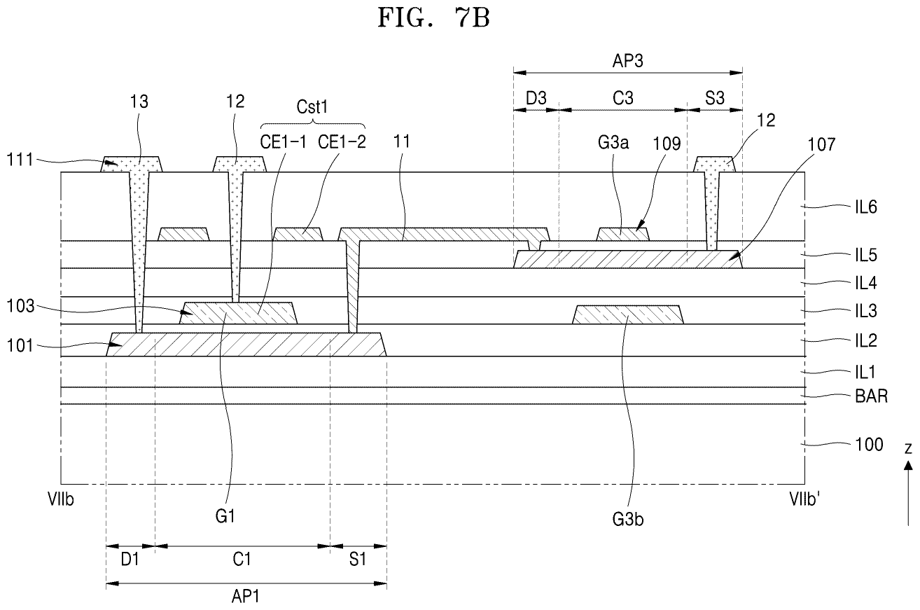

FIG. 7A is an enlarged plan view of a portion of a display apparatus according to still another embodiment. FIG. 7B is a cross-sectional view of the display apparatus of FIG. 7A, taken along line VIIb-VIIb′ of FIG. 7A.

Referring to FIGS. 7A and 7B together, the second electrode layer 105 (refer to FIG. 5B) may be omitted in a different way from the embodiment shown in FIGS. 5A and 5B.

The 3rd-2 gate electrode G3b may be disposed on the second insulating layer IL2. For example, the 3rd-2 gate electrode G3b may be disposed between the second insulating layer IL2 and the third insulating layer IL3. The 3rd-2 gate electrode G3b may be arranged in the same layer as the first gate electrode G1. In other words, the 3rd-2 gate electrode G3b and the first gate electrode G1 may be positioned in the first electrode layer 103. In some embodiments, the 3rd-2 gate electrode G3b and the first gate electrode G1 may be formed during the same process.

The 1st-2 capacitor electrode CE1-2 may be disposed on the fifth insulating layer IL5. For example, the 1st-2 capacitor electrode CE1-2 may be disposed between the fifth insulating layer IL5 and the sixth insulating layer IL6. The 1st-2 capacitor electrode CE1-2 may be arranged in the same layer as the first connection electrode 11 and the 3rd-1 gate electrode G3a. In other words, the 1st-2 capacitor electrode CE1-2, the first connection electrode 11, and the 3rd-1 gate electrode G3a may be positioned in the third electrode layer 109. In some embodiments, the 1st-2 capacitor electrode CE1-2, the first connection electrode 11, and the 3rd-1 gate electrode G3a may be formed during the same process.

In some embodiments, a separate electrode layer may not be disposed between the third insulating layer IL3 and the fourth insulating layer IL4. In other words, the second electrode layer 105 (refer to FIG. 5B) shown in FIG. 5B may be omitted. Accordingly, the third electrode layer 109 where the 1st-2 capacitor electrode CE1-2, the first connection electrode 11, and the 3rd-1 gate electrode G3a are positioned may be understood as a ‘substantially second’ electrode layer. In another embodiment, the fourth insulating layer IL4 may be omitted, and the third semiconductor pattern AP3 may be disposed on the third insulating layer IL3.

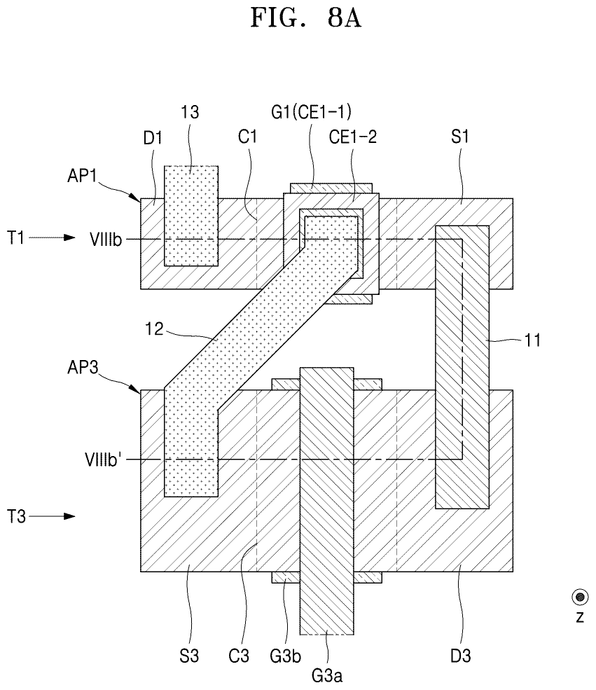

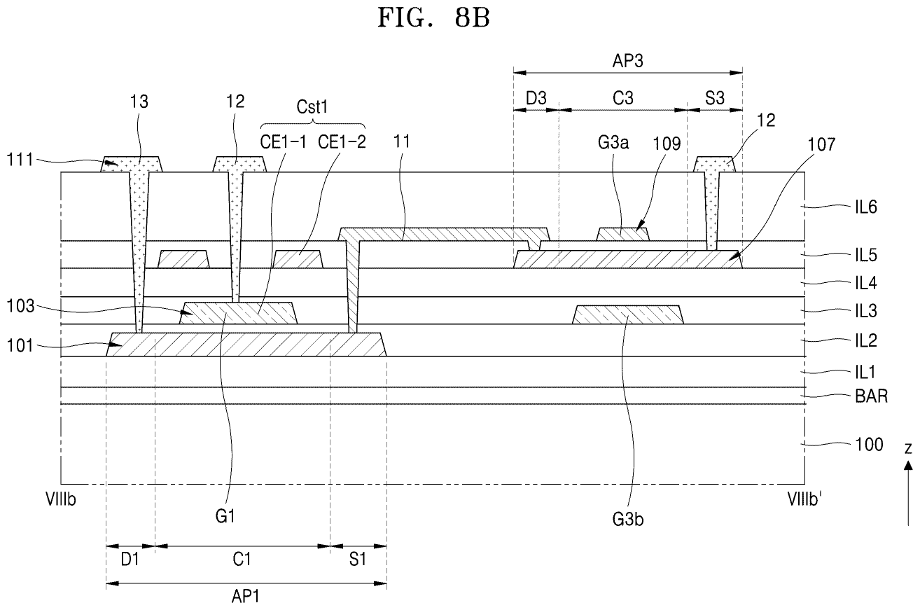

FIG. 8A is an enlarged plan view of a portion of a display apparatus according to yet another embodiment. FIG. 8B is a cross-sectional view of the display apparatus of FIG. 8A, taken along line VIIIb-VIIIb′ of FIG. 8A.

Referring to FIGS. 8A and 8B together, other features are the same as features of the embodiment shown in FIGS. 7A and 7B, but a layer in which the 1st-2 capacitor electrode CE1-2 is disposed may be different.

The 1st-2 capacitor electrode CE1-2 may be disposed on the fourth insulating layer IL4. For example, the 1st-2 capacitor electrode CE1-2 may be disposed between the fourth insulating layer IL4 and the fifth insulating layer IL5. The 1st-2 capacitor electrode CE1-2 may be arranged in the same layer as the third semiconductor pattern AP3. In other words, the 1st-2 capacitor electrode CE1-2 and the third semiconductor pattern AP3 may be positioned in the second semiconductor layer 107. In some embodiments, the 1st-2 capacitor electrode CE1-2 may include an oxide semiconductor in a similar way to the third semiconductor pattern AP3. In some embodiments, the 1st-2 capacitor electrode CE1-2 may be formed during the same process as the third semiconductor pattern AP3.

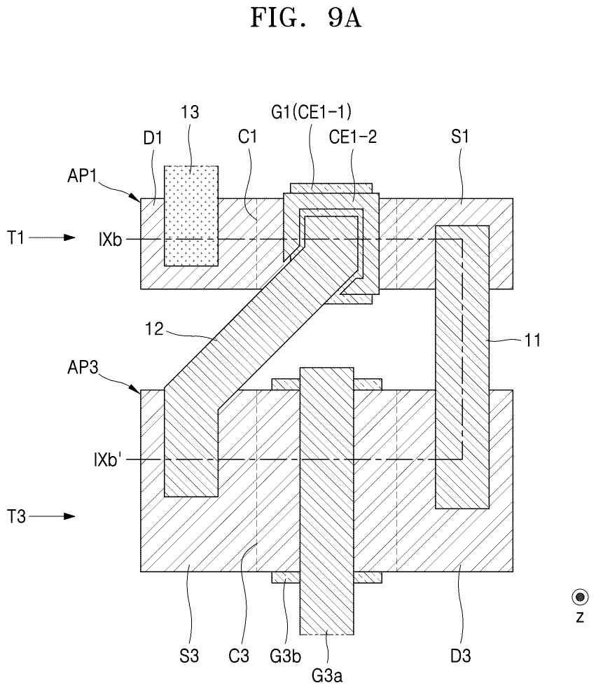

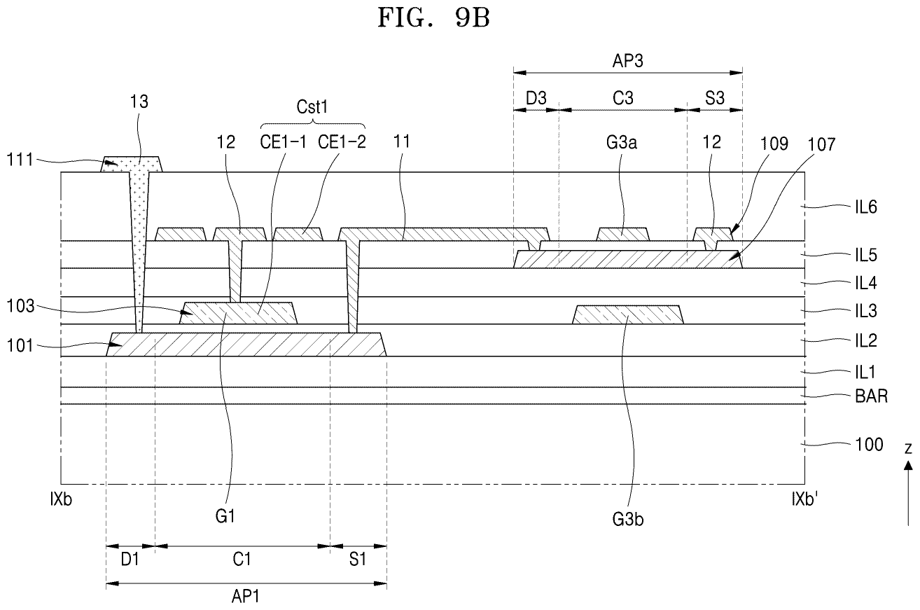

FIG. 9A is an enlarged plan view of a portion of a display apparatus according to still another embodiment. FIG. 9B is a cross-sectional view of the display apparatus of FIG. 9A, taken along line IXb-IXb′ of FIG. 9A.

Referring to FIGS. 9A and 9B together, the second connection electrode 12 may be disposed on a layer different from the layer in the embodiment shown in FIGS. 7A and 7B.

The second connection electrode 12 may be disposed on the fifth insulating layer IL5. For example, the second connection electrode 12 may be disposed between the fifth insulating layer IL5 and the sixth insulating layer IL6. The second connection electrode 12 may be arranged in the same layer as the 1st-2 capacitor electrode CE1-2, the first connection electrode 11, and the 3rd-1 gate electrode G3a. In other words, the first connection electrode 11, the second connection electrode 12, the 1st-2 capacitor electrode CE1-2, and the 3rd-1 gate electrode G3a may be positioned in the third electrode layer 109. In some embodiments, the first connection electrode 11, the second connection electrode 12, the 1st-2 capacitor electrode CE1-2, and the 3rd-1 gate electrode G3a may be formed during the same process.

The second connection electrode 12 may overlap the first gate electrode G1 in a plan view and be connected to the first gate electrode G1 through an opening defined in the third to fifth insulating layers IL3, IL4, and IL5. The second connection electrode 12 may overlap the third source region S3 in a plan view and be connected to the third source region S3 through an opening defined in the fifth insulating layer IL5.

In some embodiments, as shown in FIG. 9A, the 1st-2 capacitor electrode CE1-2 may be apart from the second connection electrode 12. The 1st-2 capacitor electrode CE1-2 may be positioned in the same layer as the second connection electrode 12 and may also overlap the first gate electrode G1 (or the 1st-1 capacitor electrode CE1-1) in a plan view. The 1st-2 capacitor electrode CE1-2 may take approximately the shape of a frame with an opening in one direction and thus may partially surround a portion of the second connection electrode 12 overlapping the first gate electrode G1 in a plan view.

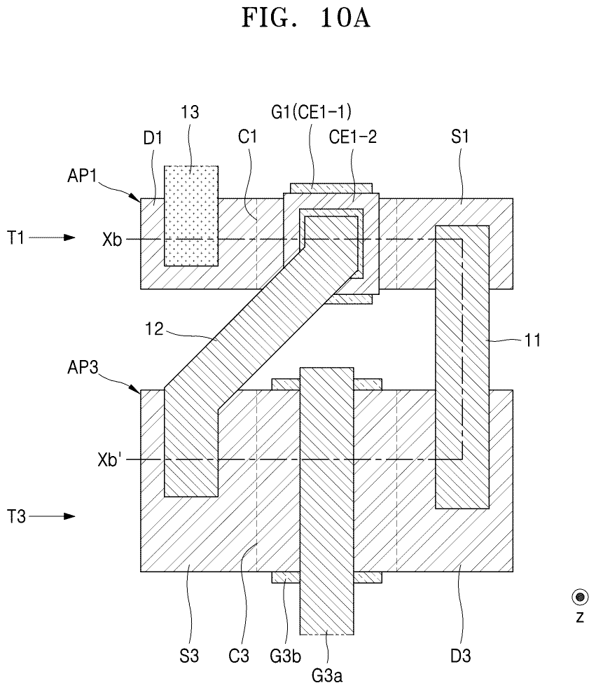

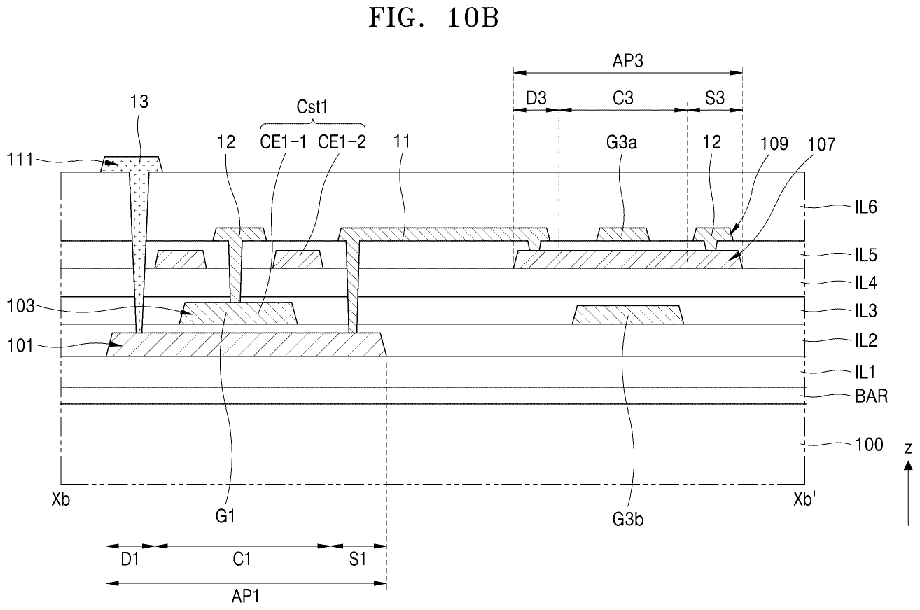

FIG. 10A is an enlarged plan view of a portion of a display apparatus according to yet another embodiment. FIG. 10B is a cross-sectional view of the display apparatus of FIG. 10A, taken along line Xb-Xb′ of FIG. 10A.

Referring to FIGS. 10A and 10B together, other features are the same as features of the embodiment shown in FIGS. 9A and 9B, but a shape of the 1st-2 capacitor electrode CE1-2 and a layer in which the 1st-2 capacitor electrode CE1-2 is disposed may be different.

The 1st-2 capacitor electrode CE1-2 may be disposed on the fourth insulating layer IL4. For example, the 1st-2 capacitor electrode CE1-2 may be disposed between the fourth insulating layer IL4 and the fifth insulating layer IL5. The 1st-2 capacitor electrode CE1-2 may be arranged in the same layer as the third semiconductor pattern AP3. In other words, the 1st-2 capacitor electrode CE1-2 and the third semiconductor pattern AP3 may be positioned in the second semiconductor layer 107. In some embodiments, the 1st-2 capacitor electrode CE1-2 may include an oxide semiconductor in a similar way to the third semiconductor pattern AP3. In some embodiments, the 1st-2 capacitor electrode CE1-2 may be formed during the same process as the third semiconductor pattern AP3.

The 1st-2 capacitor electrode CE1-2 may be arranged in a different layer than the second connection electrode 12, for example, in the second semiconductor layer 107, and accordingly, may take the shape of a complete frame without one side open unlike the embodiment shown in FIG. 9A.

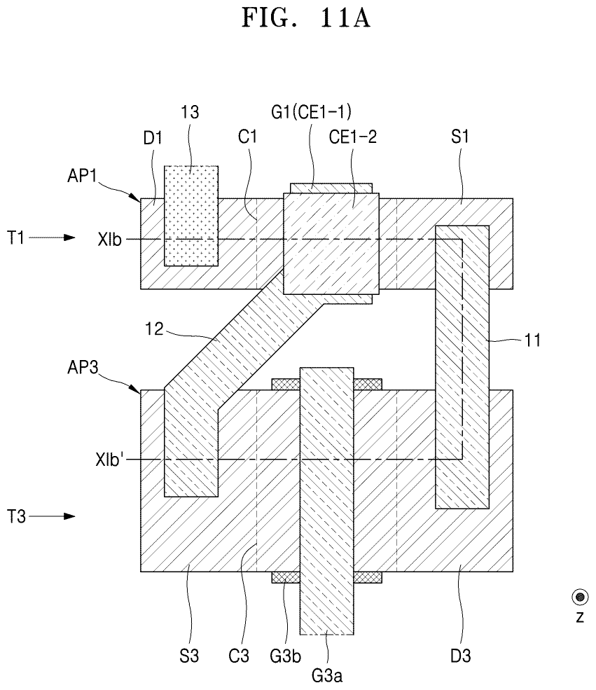

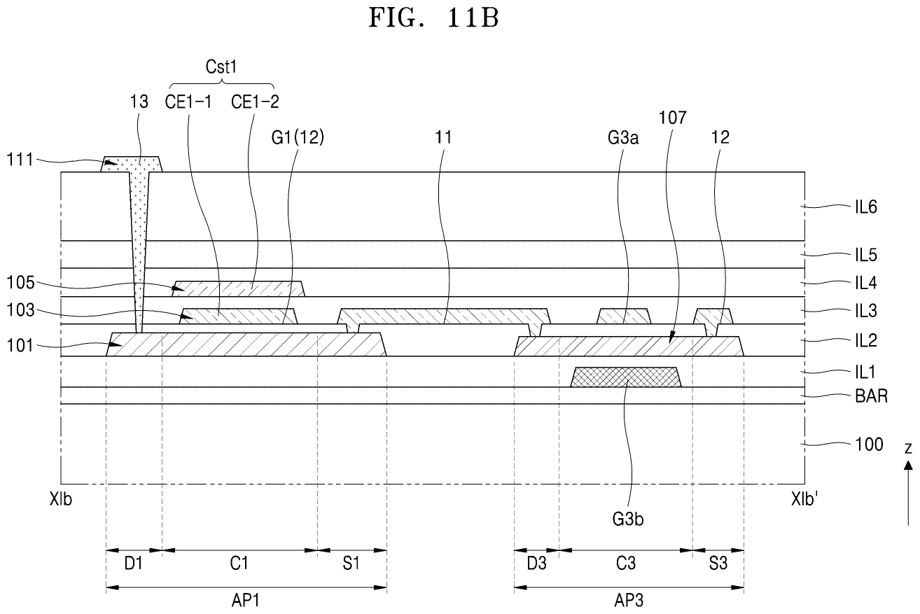

FIG. 11A is an enlarged plan view of a portion of a display apparatus according to still another embodiment. FIG. 11B is a cross-sectional view of the display apparatus of FIG. 11A, taken along line XIb-XIb′ of FIG. 11A.

Referring to FIGS. 11A and 11B together, the first semiconductor pattern AP1 and the third semiconductor pattern AP3 may both be disposed on the first insulating layer IL1. Accordingly, the first semiconductor layer 101 and the second semiconductor layer 107 may both be positioned on the first insulating layer IL1, that is, in the same layer.

The second insulating layer IL2 may be disposed over the first semiconductor layer 101 and the second semiconductor layer 107. The first gate electrode G1, the 3rd-1 gate electrode G3a, the first connection electrode 11, and the second connection electrode 12 may be disposed on the second insulating layer IL2. The first gate electrode G1, the 3rd-1 gate electrode G3a, the first connection electrode 11, and the second connection electrode 12 may be arranged in the same layer. For example, the first gate electrode G1, the 3rd-1 gate electrode G3a, the first connection electrode 11, and the second connection electrode 12 may be positioned in the first electrode layer 103. In some embodiments, the first gate electrode G1, the 3rd-1 gate electrode G3a, the first connection electrode 11, and the second connection electrode 12 may be formed during the same process.

The first gate electrode G1 and the first semiconductor pattern AP1 may be insulated by the second insulating layer IL2. The first gate electrode G1 may overlap the first channel region C1 of the first semiconductor pattern AP1 in a plan view. The 3rd-1 gate electrode G3a and the third semiconductor pattern AP3 may be insulated by the second insulating layer IL2. The 3rd-2 gate electrode G3b may be disposed under the third semiconductor pattern AP3. In some embodiments, the 3rd-2 gate electrode G3b may be disposed between the barrier layer BAR and the first insulating layer IL1. The 3rd-2 gate electrode G3b and the third semiconductor pattern AP3 may be insulated by the first insulating layer IL1. The 3rd-1 and 3rd-2 gate electrodes G3a and G3b may overlap the third channel region C3 of the third semiconductor pattern AP3 in a plan view.

The first connection electrode 11 may be connected to the first source region S1 of the first semiconductor pattern AP1 and the third drain region D3 of the third semiconductor pattern AP3. The first connection electrode 11 may overlap the first source region S1 in a plan view and be connected to the first source region S1 through a first opening in the second insulating layer IL2. The first connection electrode 11 may overlap the third drain region D3 in a plan view and be connected to the third drain region D3 through a second opening defined in the second insulating layer IL2.

The second connection electrode 12 may be connected to the third source region S3 of the third semiconductor pattern AP3. The second connection electrode 12 may overlap the third source region S3 in a plan view and be connected to the third source region S3 through an opening defined in the second insulating layer IL2. As shown in FIG. 11B, the second connection electrode 12 may be integrally formed with the first gate electrode G1. Accordingly, the first gate electrode G1 may serve both as the 1st-1 capacitor electrode CE1-1 and as a portion of the second connection electrode 12. The first gate electrode G1 and the third source region S3 may be connected to each other through the second connection electrode 12.

The third insulating layer IL3 may be disposed over the first electrode layer 103. The 1st-2 capacitor electrode CE1-2 may be disposed on the third insulating layer IL3. The 1st-2 capacitor electrode CE1-2 may be positioned in the second electrode layer 105.

The fourth to sixth insulating layers IL4, IL5, and IL6 may be sequentially disposed over the second electrode layer 105. The third connection electrode 13 may overlap the first drain region D1 in a plan view and be disposed on the sixth insulating layer IL6. The third connection electrode 13 may be connected to the first drain region D1 through an opening defined in the second to sixth insulating layers IL2, IL3, IL4, IL5, and IL6. In another embodiment, the fifth and sixth insulating layers IL5 and IL6 may be omitted, and the third connection electrode 13 may be disposed on the fourth insulating layer IL4. The third connection electrode 13 may be positioned in a fourth electrode layer 111. However, unlike the embodiment shown in FIG. 5B, the third electrode layer 109 (refer to FIG. 5B) is omitted in the embodiment shown in FIG. 11B. Accordingly, the fourth electrode layer 111 may be understood as a ‘substantially third’ electrode layer.

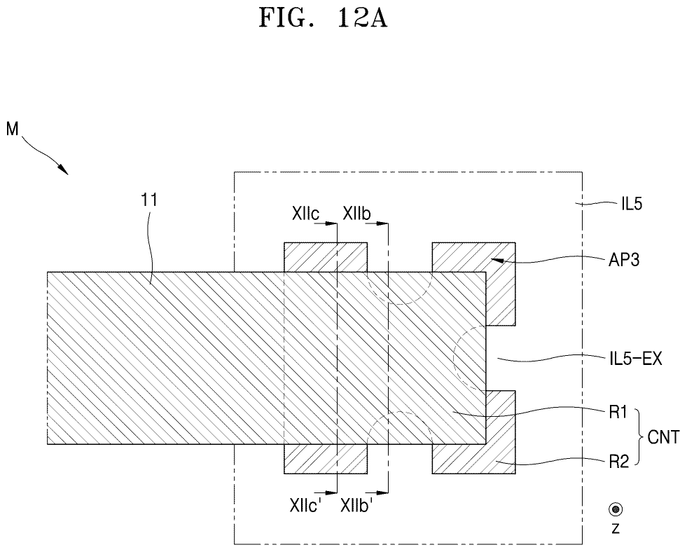

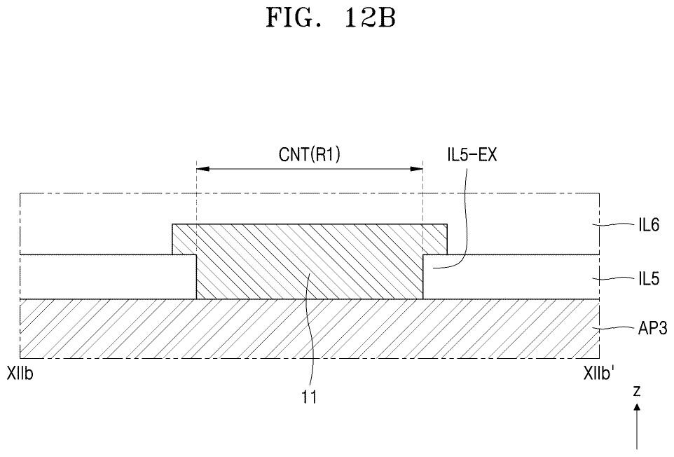

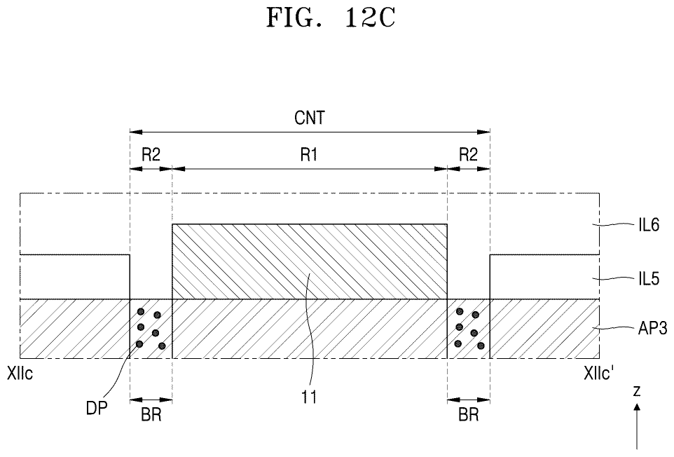

FIG. 12A is an enlarged plan view schematically showing a portion of a display apparatus according to an embodiment. FIG. 12B is a cross-sectional view of the display apparatus of FIG. 12A, taken along line XIIb-XIIb′ of FIG. 12A. FIG. 12C is a cross-sectional view of the display apparatus of FIG. 12A, taken along line XIIc-XIIc′ of FIG. 12A.

In some embodiments, FIG. 12A may be an enlarged plan view of a region M of FIG. 5B, but one or more embodiments are not limited thereto. Features of one or more embodiments that will be described below with reference to FIGS. 12A to 14 may also be similarly applied to FIGS. 6A to 11B. Accordingly, it should be understood that the following descriptions may be generally applied to the connection relationship between the third drain region D3 of the third semiconductor pattern AP3 and the first connection electrode 11 and/or the connection relationship between the third source region S3 and the second connection electrode 12.

Referring to FIG. 12A, the first connection electrode 11 may be connected to the third semiconductor pattern AP3 through an opening defined in the fifth insulating layer IL5 or a contact hole CNT.

The first connection electrode 11 may overlap the contact hole CNT in a plan view. The fifth insulating layer IL5 may include a plurality of protrusions IL5-EX protruding toward the contact hole CNT. Due to the protrusions IL5-EX, the contact hole CNT may have the shape of a curved puzzle piece in a plan view. A portion of the first connection electrode 11 may overlap the protrusions IL5-EX in a plan view. A portion of the contact hole CNT may overlap the first connection electrode 11 in a plan view, and another portion of the contact hole CNT may not overlap the first connection electrode 11 in a plan view. For example, the contact hole CNT may include a first region R1 overlapping the first connection electrode 11 in a plan view and a second region R2 not overlapping the first connection electrode 11 in the plan view. The first region R1 may be understood as a portion of the contact hole CNT that is filled by the first connection electrode 11 as the first connection electrode 11 is arranged therein. On the other hand, the second region R2 may be understood as a portion of the contact hole CNT that is not filled by the first connection electrode 11 as the first connection electrode 11 is not arranged therein and in which a portion of an upper surface of the third semiconductor pattern AP3 is exposed during at least a part of the process. As a result, the contact hole CNT may include an opening area (e.g., the second region R2) not covered by the first connection electrode 11.

Referring to FIG. 12B, the contact hole CNT may be filled by the first connection electrode 11 in the first region R1. The first connection electrode 11 may fill the contact hole CNT in the first region R1 and may be in direct contact with an upper surface of the third semiconductor pattern AP3.

The first connection electrode 11 may be in direct contact with and cover a side surface of the protrusions IL5-EX of the fifth insulating layer IL5 facing the contact hole CNT. In addition, the first connection electrode 11 may be in direct contact with and cover a portion of an upper surface of the fifth insulating layer IL5, for example, a portion of an upper surface of the protrusions IL5-EX. The sixth insulating layer IL6 may cover the fifth insulating layer IL5 and the first connection electrode 11.

Referring to FIG. 12C, the contact hole CNT may include the first region R1 in which the first connection electrode 11 is arranged and the second region R2 in which the first connection electrode 11 is not arranged.

In the first region R1, the first connection electrode 11 and the third semiconductor pattern AP3 may be in direct contact with each other. A portion of a side surface of the first connection electrode 11 may be apart from a side surface of the fifth insulating layer IL5 due to the second region R2. The second region R2 where the first connection electrode 11 and the fifth insulating layer IL5 are apart from each other may be filled by the sixth insulating layer IL6. Accordingly, in the second region R2, the sixth insulating layer IL6 and the third semiconductor pattern AP3 may be in direct contact with each other.

A process of implementing the embodiment shown in FIGS. 12A to 12C may be performed in the following order. First, the contact hole CNT may be formed by etching the fifth insulating layer IL5 disposed on the third semiconductor pattern AP3. Next, the first connection electrode 11 may be placed. Next, a portion of the third semiconductor pattern AP3 may be doped with an impurity (dopant) by injecting a dopant through the contact hole CNT. Next, the fifth insulating layer IL5 and the first connection electrode 11 may be covered by placing the sixth insulating layer IL6. In the above process, when the first connection electrode 11 completely covers the contact hole CNT, there may be no path for the dopant to reach the third semiconductor pattern AP3. According to an embodiment, because the second region R2 of the contact hole CNT is not covered by the first connection electrode 11, a portion of an upper surface of the third semiconductor pattern AP3 may be exposed in the second region R2 until the sixth insulating layer IL6 is placed. Accordingly, a portion of the third semiconductor pattern AP3 may be doped by injecting a dopant through the second region R2. The doped portion of the third semiconductor pattern AP3 is denoted as DP in FIG. 12C.

A portion of the third semiconductor pattern AP3 doped through the second region R2 may be understood as a buffer region BR of the third semiconductor pattern AP3. The buffer region BR may overlap the second region R2 in a plan view. Because the buffer region BR is a doped region and may have conductivity, the buffer region BR may electrically connect a portion of the third semiconductor pattern AP3 that is not in direct contact with the first connection electrode 11 to the first connection electrode 11. In an embodiment, a portion of the third semiconductor pattern AP3 that does not overlap the contact hole CNT in a plan view may be electrically connected to the first connection electrode 11 through the buffer region BR. For example, referring to FIGS. 12A and 12B together, a portion of the third semiconductor pattern AP3 that is under the protrusions IL5-EX of the fifth insulating layer IL5 may be electrically connected to the first connection electrode 11 through the buffer region BR.

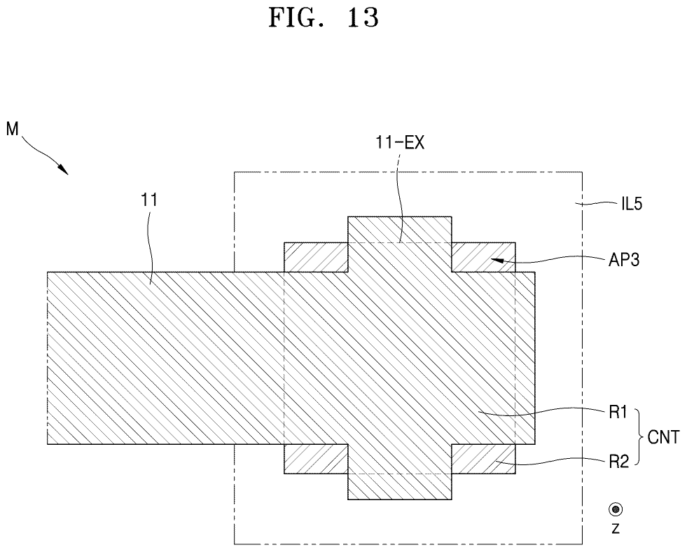

FIG. 13 is an enlarged plan view schematically showing a portion of a display apparatus according to another embodiment.

Referring to FIG. 13, the contact hole CNT may have an approximately square or rectangular shape. The first connection electrode 11 may have an approximately cross shape and may include a protrusion 11-EX protruding toward the fifth insulating layer IL5. At least a portion of the protrusion 11-EX of the first connection electrode 11 may overlap the fifth insulating layer IL5. The first region R1 of the contact hole CNT may overlap the first connection electrode 11 in a plan view, and the second region R2 may not overlap the first connection electrode 11 in the plan view.

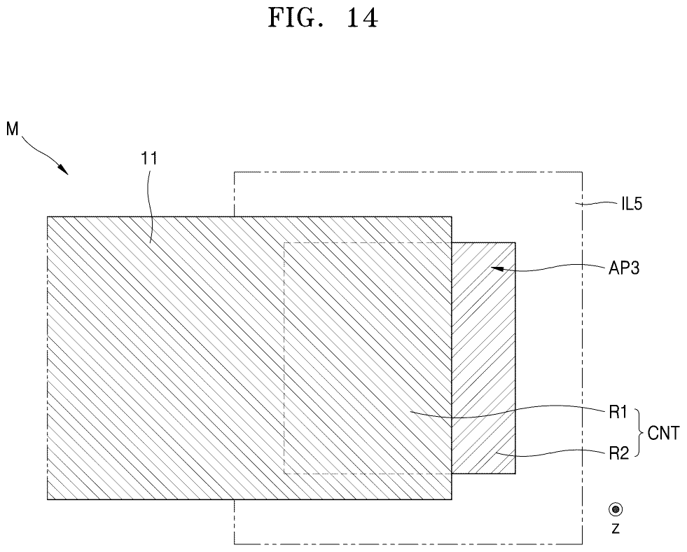

FIG. 14 is an enlarged plan view schematically showing a portion of a display apparatus according to still another embodiment.

Referring to FIG. 14, the contact hole CNT and the first connection electrode 11 may both have an approximately rectangular shape. The first connection electrode 11 may overlap only a portion of the contact hole CNT, for example, a left portion of the contact hole CNT in a plan view, and the overlapping region may be seen as the first region R1. The rest portion, for example, a right portion of the contact hole CNT, may not overlap the first connection electrode 11 in a plan view, and the corresponding region may be seen as the second region R2.

However, the disclosure is not limited to the embodiments shown in FIGS. 12A, 13 and 14, and any structure that allows the first connection electrode 11 to cover only a portion of the contact hole CNT may be included in the disclosure regardless of shapes of the first connection electrode 11 and the contact hole CNT.

According to one or more of the above embodiments, a display apparatus may be provided in which high integration of a circuit may be attained by placing a first connection electrode and a second connection electrode in the same layer as a gate electrode of the second transistor, the first connection electrode and the second connection electrode connecting a first transistor including a silicon semiconductor and a second transistor including an oxide semiconductor to each other. However, one or more embodiments are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate on which a display element is arranged;
a first transistor arranged on the substrate and comprising a first semiconductor pattern comprising a silicon semiconductor and a first gate electrode insulated from the first semiconductor pattern and arranged over the first semiconductor pattern;
a second transistor arranged on the substrate and comprising a second semiconductor pattern comprising an oxide semiconductor and a 2nd-1 gate electrode insulated from the second semiconductor pattern and arranged over the second semiconductor pattern; and
a first connection electrode connecting the first semiconductor pattern and the second semiconductor pattern to each other,
wherein the first connection electrode is arranged in a same layer in which the 2nd-1 gate electrode is arranged.

2. The display apparatus of claim 1, further comprising a second connection electrode connecting the first gate electrode and the second semiconductor pattern to each other.

3. The display apparatus of claim 2, wherein the second connection electrode is arranged in the same layer in which the first connection electrode is arranged.

4. The display apparatus of claim 1, further comprising a 2nd-2 gate electrode insulated from the second semiconductor pattern and arranged under the second semiconductor pattern.

5. The display apparatus of claim 1, further comprising a capacitor electrode insulated from the first gate electrode and arranged over the first gate electrode,
wherein the first connection electrode and the capacitor electrode are arranged in the same layer.

6. The display apparatus of claim 4, wherein the first gate electrode and the 2nd-2 gate electrode are arranged in a same layer.

7. The display apparatus of claim 1, wherein the first semiconductor pattern and the second semiconductor pattern are arranged in a same layer.

8. The display apparatus of claim 1, wherein the first connection electrode is connected to the second semiconductor pattern through a contact hole defined in an insulating layer arranged between the first connection electrode and the second semiconductor pattern,
wherein, in a plan view, the contact hole comprises a first region overlapping the first connection electrode and a second region not overlapping the first connection electrode.

9. The display apparatus of claim 8, wherein the first connection electrode and a side surface of the insulating layer facing the first region are in direct contact with each other.

10. The display apparatus of claim 8, further comprising another insulating layer covering the first connection electrode,
wherein the second semiconductor pattern are in direct contact with the another insulating layer in the second region.

11. A display apparatus comprising:
a substrate;
a first transistor arranged on the substrate and comprising a first semiconductor pattern comprising a silicon semiconductor and a first gate electrode insulated from the first semiconductor pattern and arranged over the first semiconductor pattern, wherein the first semiconductor pattern comprises a first channel region overlapping the first gate electrode and a first source region and a first drain region, which are disposed on two sides of the first channel region opposite to each other;
a second transistor arranged on the substrate, comprising a second semiconductor pattern comprising an oxide semiconductor and a 2nd-1 gate electrode insulated from the second semiconductor pattern and arranged over the second semiconductor pattern, and electrically connected to the first transistor, wherein the second semiconductor pattern comprises a second channel region overlapping the 2nd-1 gate electrode and a second source region and a second drain region, which are disposed on two sides of the second channel region opposite to each other;
a first connection electrode connected to one of the first source region and the first drain region of the first semiconductor pattern;
a second connection electrode connected to one of the second source region and the second drain region of the second semiconductor pattern; and
an insulating layer arranged between the first connection electrode and the second connection electrode,
wherein the second connection electrode is arranged under the insulating layer, and the first connection electrode is arranged on the insulating layer.

12. The display apparatus of claim 11, wherein a first portion of the second connection electrode is connected to the one of the second source region and the second drain region of the second semiconductor pattern, and a second portion of the second connection electrode is connected to the other one of the first source region and the first drain region of the first semiconductor pattern.

13. The display apparatus of claim 11, wherein a first portion of the second connection electrode is connected to the one of the second source region and the second drain region of the second semiconductor pattern, and a second portion of the second connection electrode is connected to the first gate electrode.

14. The display apparatus of claim 11, wherein the second connection electrode and the 2nd-1 gate electrode are arranged in a same layer.

15. The display apparatus of claim 11, further comprising a capacitor electrode arranged over the first gate electrode and insulated from the first gate electrode,
wherein the second connection electrode and the capacitor electrode are arranged in a same layer.

16. The display apparatus of claim 11, further comprising a capacitor electrode arranged over the first gate electrode and insulated from the first gate electrode,
wherein the second semiconductor pattern and the capacitor electrode are arranged in a same layer.

17. The display apparatus of claim 11, further comprising a 2nd-2 gate electrode insulated from the second semiconductor pattern and arranged under the second semiconductor pattern.

18. The display apparatus of claim 11, wherein the second connection electrode and the first gate electrode are arranged in a same layer.

19. The display apparatus of claim 11, wherein the first semiconductor pattern and the second semiconductor pattern are arranged in a same layer.

20. The display apparatus of claim 11, wherein the second connection electrode is connected to the one of the second source region and the second drain region of the second semiconductor pattern through a contact hole defined in another insulating layer arranged between the second connection electrode and the second semiconductor pattern,
wherein, in a plan view, the contact hole comprises a first region overlapping the second connection electrode and a second region not overlapping the second connection electrode,
wherein the second semiconductor pattern comprises a buffer region overlapping the second region.
